(19) United States
(12) Patent Application Publication
(10) Pub. No.: US 2025/0024717 A1
(43) Pub. Date: Jan. 16, 2025

(54) DISPLAY DEVICE AND MANUFACTURING METHOD THEREOF

(71) Applicant: Samsung Display Co., Ltd., Yongin-Si (KR)

(72) Inventors: Jeonghyun LEE, Yongin-si (KR); Jin Woo LEE, Yongin-si (KR); Ji Eun CHOI, Yongin-si (KR); Rakyoung KIM, Yongin-si (KR); Hyunwoo KIM, Yongin-si (KR); Sangkyung BAE, Yongin-si (KR)

(21) Appl. No.: 18/443,311

(22) Filed: Feb. 16, 2024

(30) Foreign Application Priority Data
Jul. 13, 2023 (KR) 10-2023-0091014

(51) Int. Cl. H10K 59/131; H10K 59/12; H10K 59/121; H10K 59/123; H10K 59/124; H10K 71/16; H10K 71/60

(52) U.S. Cl. CPC H10K 59/131; H10K 59/1201; H10K 59/1213; H10K 59/123; H10K 59/124; H10K 71/166; H10K 71/60

(57) ABSTRACT

A display device includes a display area including multiple pixels and a separator extending around the pixels, and a peripheral area located around the display area and including a scan driver and an electrostatic element part. Each pixel includes a pixel electrode, a light emitting auxiliary layer, and a common electrode. The light-emitting auxiliary layer is disconnected at the separator between neighboring pixels. The electrostatic element unit includes a first voltage line electrically connected to the scan driver, and multiple electrostatic elements electrically connected to the first voltage line. Multiple contact holes overlap the first voltage line located in the electrostatic element unit, and an insulating layer is located in the contact holes.

### CROSS-REFERENCE TO RELATED APPLICATION

This application claims priority to and the benefit of Korean Patent Application No. 10-2023-0091014 filed at the Korean Intellectual Property Office on Jul. 13, 2023, the entire contents of which are incorporated herein by reference.

### BACKGROUND

### Technical Field

The present disclosure relates to a display device and a manufacturing method thereof.

### Description of the Related Art

A display device is a device that displays an image and may include a liquid crystal display (LCD), an organic light emitting diode (OLED), and the like. Such display devices may be used in various electronic devices such as mobile phones, navigation devices, digital cameras, electronic books, portable game consoles, and various terminals.

One type of display device includes a plurality of pixels that include light emitting diodes, which are self-luminous elements, and each pixel may further include a plurality of transistors and at least one capacitor for driving the light emitting diode or diodes in the pixel. The plurality of pixels may include pixels capable of emitting light of different colors.

A light emitting diode may include two electrodes and a light emitting layer and/or a light emitting auxiliary layer positioned therebetween. During operation, electrons injected from one electrode and holes injected from the other electrode may combine in the light emitting layer and releases energy, which may be in the form of emitted light.

Manufacturing of a display device generally includes processes stacking and patterning several layers on a substrate, and transferring the substrate is required between processes.

### SUMMARY

Embodiments disclosed herein may prevent spots from appearing on a display device by preventing display defects due to leakage current between pixels of the display device or by preventing changes in transistor characteristics due to charging during a manufacturing process.

A display device according to an embodiment includes a display area including a plurality of pixels and a separator extending around the pixels, and a peripheral area positioned around the display area and including a scan driver and an electrostatic element unit. Each of the pixels includes a pixel electrode, a portion of a light emitting auxiliary layer positioned on the pixel electrode, and a portion of a common electrode positioned on the auxiliary light emitting layer. Between adjacent pixels, the separator disconnects portions of the light emitting auxiliary layer. The electrostatic element unit includes a first voltage line electrically connected to the scan driver and a plurality of electrostatic elements electrically connected to the first voltage line. A plurality of contact holes overlapping the first voltage line are located in the electrostatic element unit, and an insulating layer is in the contact hole.

A passivation layer positioned on the first voltage line and having the contact hole formed therein may be further included, and the insulating layer may contact a side surface of the passivation layer defining the contact hole and an upper surface of the first voltage line.

The insulating layer may include a portion located on an upper surface of the passivation layer.

A pixel insulating layer positioned on the passivation layer and the pixel electrode may further be included, and a separator may be formed in a concave shape on an upper surface of the pixel insulating layer.

The display device may further include a substrate and a transistor disposed between the substrate and the passivation layer, and the pixel electrode may be electrically connected to the transistor.

The includes multiple data lines connected to the multiple electrostatic elements, the multiple data lines cross the first voltage line, and the multiple contact holes can be located between neighboring data lines on a plane.

The electrostatic element unit may further include an electrostatic semiconductor layer forming the plurality of electrostatic elements, and the plurality of contact holes may not overlap the electrostatic semiconductor layer on a plane.

Residue containing a metal oxide may be further included in a partial region within the contact hole.

A light emitting layer positioned between the pixel electrode and the common electrode or between the light emitting auxiliary layer and the pixel electrode may be further included.

The display device according to an embodiment includes a substrate including a display area and a peripheral area positioned outside the display area, a transistor positioned over the display area, an electrostatic element positioned over the peripheral area, and a first electrode electrically connected to the electrostatic element, a first voltage line and a second voltage line, a passivation layer positioned on the transistor, the first voltage line and the second voltage line, a plurality of pixel electrodes positioned on the passivation layer and positioned in the display area, and a pixel positioned on the passivation layer and the pixel electrode, an insulating layer, and a light emitting auxiliary layer and a light emitting layer positioned on the pixel electrode and the pixel insulating layer, wherein the pixel insulating layer is positioned between adjacent pixel electrodes among the plurality of pixel electrodes and includes a concave separator, and the passivation layer has a contact hole positioned on the first voltage line in the peripheral area.

The passivation layer may cover all of the second voltage line in the peripheral area.

It further includes a plurality of data lines connected to the plurality of electrostatic elements, the data lines cross the first voltage line and the second voltage line, and the plurality of contact holes are formed on a plane of the plurality of data lines, and it may be located between adjacent data lines.

The electrostatic element unit may further include an electrostatic semiconductor layer forming the plurality of electrostatic elements, and the plurality of contact holes may not overlap the electrostatic semiconductor layer on a plane.

Residue containing a metal oxide may be further included in a partial region within the contact hole.

An insulating layer including a portion positioned within the contact hole and contacting a side surface of the passivation layer defining the contact hole and an upper surface of the first voltage line may be further included.

The insulating layer may include a portion located on an upper surface of the passivation layer.

The light emitting auxiliary layer may be disconnected from the separator.

A method of manufacturing a display device according to an embodiment includes forming a plurality of transistors positioned on a display area on a substrate, forming a plurality of electrostatic elements and voltage lines positioned in a peripheral area around the display area, stacking a passivation layer on the voltage line, forming a contact hole exposing the voltage line located in the peripheral area in the passivation layer, forming a plurality of pixel electrodes in the display area, and forming a pixel insulating layer on the pixel electrode, forming a first opening on the pixel electrode by patterning the pixel insulating layer, depositing a mask layer on the entire surface of the substrate, and patterning the mask layer to form a first opening positioned on the pixel electrode, forming a second opening positioned between neighboring pixel electrodes, removing a portion of the upper surface of the pixel insulating layer corresponding to the second opening using the second opening as a mask to form a concave hole on the upper surface of the pixel insulating layer forming a separator, and removing the mask layer on the entire surface of the substrate, wherein the stacked mask layer is electrically connected to the voltage line through the contact hole.

The mask layer may include a metal oxide.

The process includes the steps of stacking a light emitting auxiliary layer on the pixel electrode and the pixel insulating layer, forming a common electrode on the light emitting auxiliary layer, and forming an insulating layer on the substrate, the light emitting auxiliary layer may include a portion cut off from the separator, and the insulating layer may include a portion located inside the contact hole.

According to the embodiments, display defects due to leakage current between a plurality of pixels of a display device may be prevented, and a change in characteristics of a transistor due to charging during a manufacturing process may be prevented to prevent spots from appearing.

### BRIEF DESCRIPTION OF THE DRAWINGS

FIG. 1 is a plan view of a display device according to an embodiment.

FIG. 2 is a plan view of a portion of a display area of a display device according to an embodiment.

FIG. 3 is a cross-sectional view of one pixel of a display area of a display device according to an embodiment.

FIG. 4 is a plan view of an electrostatic element unit in a peripheral area of a display device according to an embodiment.

FIG. 5 is a circuit diagram of an electrostatic element unit in a peripheral area of a display device according to an embodiment.

FIG. 6, FIG. 7 and FIG. 8 are cross-sectional views of the display device shown in FIG. 4 taken along the line A1-A2.

FIG. 9 is a circuit diagram of an electrostatic element unit in a peripheral area of a display device according to an embodiment.

FIG. 10, FIG. 11 and FIG. 12 are cross-sectional views of the display device shown in FIG. 9 taken along line B1-B2.

FIG. 13, FIG. 14, FIG. 15, FIG. 16, FIG. 17, FIG. 18, FIG. 19 and FIG. 20 are cross-sectional views of structures formed during a method of manufacturing a display device according to an embodiment.

FIG. 21, FIG. 22, FIG. 23 and FIG. 24 are cross-sectional views of a display device in one manufacturing process of a display device according to an embodiment.

FIG. 25 is a cross-sectional view of a display device in one manufacturing process of a display device according to a comparative example, and

FIG. 26 and FIG. 27 illustrate a manufacturing process of a display device according to a comparative example and stains displayed on an image of the display device.

### DETAILED DESCRIPTION OF THE EMBODIMENTS

Various embodiments in accordance with the present disclosure will be described in detail with reference to the accompanying drawings so that those skilled in the art can make or use the embodiments. The disclosed embodiments may take many different forms, and this disclosure is not limited to the specific embodiments set forth herein. In order to provide a clear description, parts or elements that are well known or irrelevant to the description may be omitted.

In the drawings, the same reference numerals are assigned to the same or similar components throughout the specification. In addition, the shape, size, or thickness of each component in the drawings may be altered for convenience of explanation, and the present disclosure is not necessarily limited to that which is shown. For example, in the drawings, thicknesses may be enlarged or exaggerated to clearly express the various layers and regions or for convenience of explanation.

In the description, when a part such as a layer, film, region, or plate is said to be “above” or “on” another part, this includes not only the case where the part is “directly on” the other part, but also the case where yet another part exists is between the two other parts. Conversely, a part said to be “directly on” another part means that there is no other part in between.

In addition, being “above” or “on” a reference part means being located above or below the reference part and does not necessarily mean being located “above” or “on” it in the opposite direction of gravity.

In addition, throughout the specification, a part said to “include” a component means that the part may further include other components without excluding other components, unless expressly stated otherwise.

Also, throughout the specification, reference to a “planar image” means a view of the target part from above a major surface of the part, and reference to a “cross-sectional image” means the target part is cut along a section line and is viewed from perpendicular to the cut.

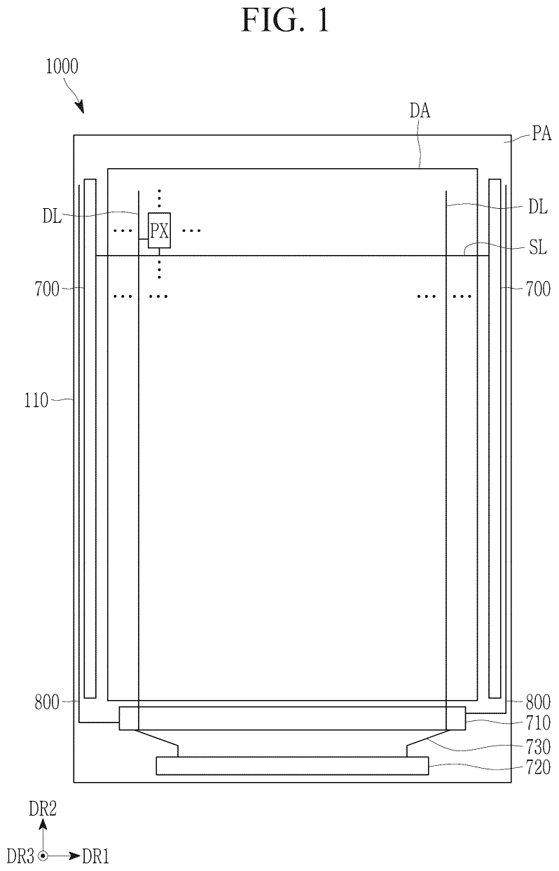

A display device according to an embodiment will be described with reference to FIG. 1 to FIG. 12.

FIG. 1 is a top plan view of a display device 1000 according to an embodiment. A view looking at surface extending in first and second directions DR1 and DR2 may be referred to herein as a plan view, and a view looking at the cross-section perpendicular to a plan view may be referred to herein as a cross-section view.

Referring to FIG. 1, the display device 1000 includes a substrate 110 including a display area DA, which is an area capable of displaying an image, and a peripheral area PA, which is around the display area DA may be included. The display area DA may include a plurality of pixels PC that may be used to display an image. The peripheral area PA may or may not display an image and may or may not include pixels PX capable of displaying an image.

The substrate 110 has a major surface parallel to the first direction DR1 and the second direction DR2 perpendicular to the first direction DR1, and a direction perpendicular to the major surface of the substrate 110 may be referred to herein as upward or as a third direction DR3.

The display area DA may include a plurality of pixels PX, which are units capable of displaying an image. Each pixel PX may include at least one transistor, a light emitting device, and a capacitor.

The display area DA may also include a plurality of signal lines or voltage lines electrically connected to the pixels PX to apply signals or voltages. The plurality of signal lines or the plurality of voltage lines may include a plurality of scan lines SL capable of transmitting scan signals to the pixels PX and a plurality of data lines DL capable of transmitting data signals to the pixels PX. In a plan view, the data line DL may extend substantially in the second direction DR2 but is not limited thereto. In a plan view, the scan line SL may extend substantially in the first direction DR1 but is not limited thereto.

The peripheral area PA can include a scan driver 700 that is connected to multiple scan lines SL and can supply scan signals, an electrostatic element unit 710, a wiring extension part 730, and a pad unit 720.

The scan driver 700 may include a transistor directly formed on the substrate 110 together with a transistor positioned in the display area DA. Portions of the scan driver 700 may be located in left and right portions of the peripheral areas PA with respect to the display area DA, but the scan driver 700 is not limited thereto and may be located in only one peripheral area PA. The scan line SL may extend to the peripheral area PA and be connected to the scan driver 700.

The electrostatic element unit 710 may be positioned in the peripheral area PA below and/or above the display area DA and may include a plurality of electrostatic diodes or a plurality of electrostatic transistors on the substrate 110, it can discharge the static electricity charged in it. The data lines DL may extend to the peripheral area PA and be connected to the electrostatic element unit 710.

The pad unit 720 may be positioned close to an edge of the substrate 110 adjacent to the peripheral area PA where the electrostatic element unit 710 is located. That is, the electrostatic element unit 710 may be positioned between the pad unit 720 and the display area DA.

The data lines DL passing through the electrostatic element unit 710 may extend to the pad unit 720 and be electrically connected to a plurality of pads located on the pad unit 720. The data lines DL extending to the peripheral area PA may include a wire extension part 730. The wire extension part 730 may be located between the electrostatic element unit 710 and the pad unit 720 and may include a plurality of wires connecting the electrostatic element unit 710 and the pad unit 720. The wire extension part 730 may form a fan-out shape in which a gap or spacing between wires in the extension part 730 may be wider at the electrostatic element unit 710 and may narrow toward the pad unit 720.

The substrate 110 may be bent in an area where the wire extension part 730 is located, and the peripheral area PA where the pad unit 720 is located may be folded toward the rear surface of the substrate 110. A data driver supplying a data signal and/or a driving voltage may be mounted on the pad unit 720 in the form of an integrated circuit chip or a circuit board.

A voltage line 800 electrically connected to the scan driver 700 and the electrostatic element unit 710 may be located in the peripheral area PA. The voltage line 800 may include a portion extending substantially in the second direction DR2 along an edge of the substrate 110 adjacent to the peripheral area PA where the scan driver 700 is located. The voltage line 800 may transfer a certain voltage to the scan driver 700 and the electrostatic element unit 710. The voltage line 800 may include two or more voltage lines delivering two or more voltages.

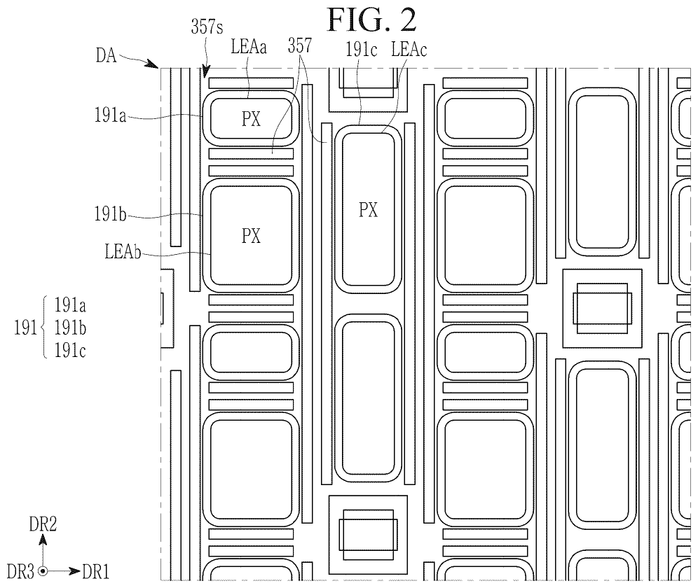

FIG. 2 is a plan view of a portion of a display area of a display device according to an embodiment.

Referring to FIG. 2, a plurality of pixel electrodes 191 corresponding to each pixel PX are positioned in the display area DA. Each pixel electrode 191 may be an anode electrode of a light emitting device but is not limited thereto. A group of pixel electrodes 191 adjacent to each other may include a plurality of pixel electrodes 191a, 191b, and 191c having different planar sizes. Light emitting regions LEAa, LEAb, and LEAc, which are regions emitting light from each pixel, may be positioned to overlap the corresponding pixel electrodes 191a, 191b, and 191c. A group of light emitting regions LEAa, LEAb, and LEAc adjacent to each other may emit light of different colors. For example, the light emitting region LEAa may emit red light, the light emitting region LEAb may emit green light, and the light emitting region LEAc may emit blue light.

The display area DA may include a separator 357 extending around each of the pixel electrodes 191a, 191b, and 191c. Each separator 357 can be a structure that disconnects and separates at least one layer or region that constitutes a light emitting device—i.e., an anode electrode layer, a cathode electrode layer, a light emitting layer, a light emitting auxiliary layer, from at least one layer or region of neighboring light emitting regions LEAa, LEAb, LEAc or neighboring pixels. Each separator 357 may protrude in the third direction DR3 or may have a concave shape.

The plurality of separators 357 positioned around one pixel electrode 191a, 191b, or 191c and extending in different directions may be separated from each other without being connected to each other. That is, the plurality of separators 357 positioned around one pixel electrode 191a, 191b, or 191c and extending in different directions may not form a closed curve shape, and a spaced area 357s may be located between adjacent separators 357.

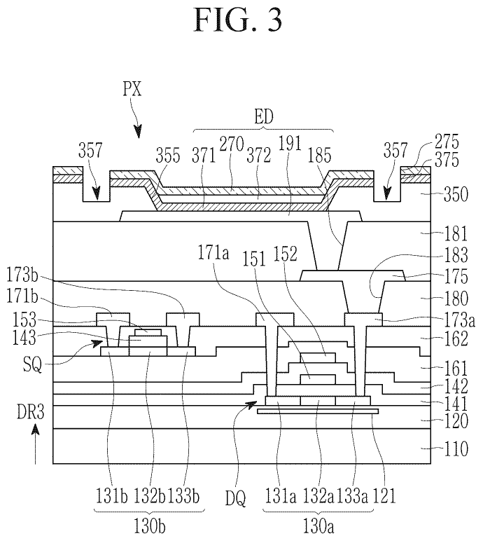

FIG. 3 is a cross-sectional view of one pixel of a display area of a display device according to an embodiment.

Referring to FIG. 3, a first insulating layer 120 may be positioned on the substrate 110. The substrate 110 may include a rigid material, such as glass, that does not bend, or may include a flexible material that can bend, such as plastic or polyimide. The first insulating layer 120 may also be referred to as a buffer layer. The first insulating layer 120 may include an inorganic insulating material or an organic insulating material such as silicon oxide (SiOx), silicon nitride (SiNx), and silicon oxynitride (SiOxNy).

A first semiconductor layer 130a of a first transistor DQ, which may be a driving transistor, may be positioned on the first insulating layer 120. The first semiconductor layer 130a may include a channel region 132a and a first electrode 131a and a second electrode 133a connected to opposite sides of the channel region 132a. The first semiconductor layer 130a may include, for example, a polycrystalline semiconductor material.

A lower layer 121 may be further positioned between the first semiconductor layer 130a and the substrate 110. The lower layer 121 may block light that might otherwise be incident on the first semiconductor layer 130a and may include a metal or metal alloy such as copper (Cu), molybdenum (Mo), aluminum (Al), or titanium (Ti). Alternatively, the lower layer 121 may include amorphous silicon, and the lower layer 121 may be composed of a single layer or multiple layers.

A first gate insulating layer 141 may be positioned on the first semiconductor layer 130a. The first gate insulating layer 141 may have a single-layer or multi-layer structure. The first gate insulating layer 141 may include an inorganic insulating material such as silicon nitride (SiNx), silicon oxide (SiOx), or silicon oxynitride (SiOxNy).

A first gate conductive layer including the gate electrode 151 of the first transistor DQ may be positioned on the first gate insulating layer 141. The first gate conductive layer may have a single-layer or multi-layer structure. The first gate conductive layer may include a metal material such as molybdenum (Mo), aluminum (Al), copper (Cu), and/or titanium (Ti). The gate electrode 151 of the first transistor DQ may overlap the channel region 132a of the first transistor DQ.

A second gate insulating layer 142 may be positioned on the first gate conductive layer and the first gate insulating layer 141. The second gate insulating layer 142 may have a single-layer or multi-layer structure. The second gate insulating layer 142 may include an inorganic insulating material such as silicon nitride (SiNx), silicon oxide (SiOx), or silicon oxynitride (SiOxNy).

A second gate conductive layer including a storage electrode 152 may be positioned on the second gate insulating layer 142. The second gate conductive layer may have a single-layer or multi-layer structure. The second gate conductive layer may include a metal material such as molybdenum (Mo), aluminum (Al), copper (Cu), and/or titanium (Ti). The storage electrode 152 may overlap the gate electrode 151 of the first transistor DQ with the second gate insulating layer 142 therebetween to form a capacitor. A driving voltage may be transmitted to the storage electrode 152.

A first interlayer insulating layer 161 may be positioned on the second gate conductive layer and the second gate insulating layer 142. The first interlayer insulating layer 161 may have a single-layer or multi-layer structure. The first interlayer insulating layer 161 may include an inorganic insulating material such as silicon nitride (SiNx), silicon oxide (SiOx), or silicon oxynitride (SiOxNy).

A second semiconductor layer 130b of the second transistor SQ, which may be a switching transistor, may be positioned on the first interlayer insulating layer 161. The second semiconductor layer 130b may include a channel region 132b and a first electrode 131b, and a second electrode 133b connected to opposite sides of the channel region 132b. The second semiconductor layer 130b may include, for example, an oxide semiconductor material. For example, the second semiconductor layer 130b may include a 1-element metal oxide such as indium oxide (In₂O₃), tin oxide (SnO₂), or zinc oxide (ZnO), an In—Zn-based oxide, an Sn—Zn-based oxide, binary metal oxides such as Zn—Mg-based oxide, Sn—Mg-based oxide, In—Mg-based oxide or In—Ga-based oxide, ternary metal oxides such as In—Ga—Zn-based oxide, In—Al—Zn-based oxide, In—Sn—Zn oxide, Sn—Ga—Zn oxide, Al—Ga—Zn oxide, Sn—Al—Zn oxide, In—Hf—Zn oxide, In—La—Zn oxide, In—Ce—Zn oxide, In—Pr—Zn oxide, In—Nd—Zn oxide, In—Sm—Zn oxide, In—Eu—Zn oxide, In—Gd—Zn oxide, In—Tb—Zn-based oxide, In—Dy—Zn-based oxide, In—Ho—Zn-based oxide, In—Er—Zn-based oxide, In—Tm—Zn-based oxide, In—Yb—Zn-based oxide or In—Lu—Zn-based oxide, quaternary metal oxides such as In—Sn—Ga—Zn oxides, In—Hf—Ga—Zn oxides, In—Al—Ga—Zn oxides, or In—Sn—Al—Zn oxides. The semiconductor layer 130b may include at least one of an Sn—Hf—Zn-based oxide or an In—Hf—Al—Zn-based oxide. For example, the oxide semiconductor layer may include indium-gallium-zinc oxide (IGZO) among the In—Ga—Zn-based oxides.

The second gate conductive layer may further include a light blocking layer overlapping or underlying the second semiconductor layer 130b.

A third gate insulating layer 143 may be positioned on the second semiconductor layer 130b. The third gate insulating layer 143 may be formed on the entire surface of the substrate 110, and as shown in FIG. 3, the third gate insulating layer 143 overlaps the channel region 132b of the second semiconductor layer 130b, and the third gate insulating layer 142 may be patterned so as not to overlap with the rest of 130b. The third gate insulating layer 143 may have a single-layer or multi-layer structure. The third gate insulating layer 143 may include an inorganic insulating material such as silicon nitride (SiNx), silicon oxide (SiOx), or silicon oxynitride (SiOxNy).

A third gate conductive layer including the gate electrode 153 of the second transistor SQ may be positioned on the third gate insulating layer 143. The third gate conductive layer may have a single-layer or multi-layer structure. The third gate conductive layer may include a metal material such as molybdenum (Mo), aluminum (Al), copper (C), and/or titanium (Ti). The gate electrode 153 of the second transistor SQ may overlap the channel region 132b of the second transistor SQ.

A second interlayer insulating layer 162 may be positioned on the third gate conductive layer. The second interlayer insulating layer 162 may have a single-layer or multi-layer structure. The second interlayer insulating layer 162 may include an inorganic insulating material such as silicon nitride (SiNx), silicon oxide (SiOx), or silicon oxynitride (SiOxNy).

A first data conductive layer including a plurality of connection electrodes 171a, 171b, 173a, and 173b may be positioned on the second interlayer insulating layer 162.

The connection electrode 171a is connected to the first transistor DQ through contact holes formed in the first gate insulating layer 141, the second gate insulating layer 142, the first interlayer insulating layer 161, and the second interlayer insulating layer 162. The connection electrode 171a may be electrically connected to the first electrode 131a of the first transistor DQ.

The connection electrode 173a is connected to the first transistor DQ through contact holes formed in the first gate insulating layer 141, the second gate insulating layer 142, the first interlayer insulating layer 161, and the second interlayer insulating layer 162, and the connection electrode 173a may be electrically connected to the second electrode 133a of the first transistor DQ.

The connection electrode 171b may be electrically connected to the first electrode 131b of the second transistor SQ through a contact hole formed in the second interlayer insulating layer 162.

The connection electrode 173b may be electrically connected to the second electrode 133b of the second transistor SQ through a contact hole formed in the second interlayer insulating layer 162.

A first passivation layer 180 may be positioned on the first data conductive layer.

A second data conductive layer including a connection electrode 175 may be positioned on the first passivation layer 180. The second data conductive layer may include a data line. The connection electrode 175 is electrically connected to the connection electrode 173a of the first data conductive layer through the contact hole 183 in the first passivation layer 180, and through this, the second electrode 133a of the first transistor DQ it is electrically connected.

Each of the first data conductive layer and the second data conductive layer may have a single-layer or multi-layer structure. The first data conductive layer and the second data conductive layer may include aluminum (Al), platinum (Pt), palladium (Pd), silver (Ag), magnesium (Mg), gold (Au), nickel (Ni), or neodymium (Nd), iridium (Ir), chromium (Cr), calcium (Ca), molybdenum (Mo), titanium (Ti), tungsten (W), and/or copper (Cu).

A second passivation layer 181 may be positioned on the second data conductive layer.

Each of the first passivation layer 180 and the second passivation layer 181 may have a single-layer or multi-layer structure. The first passivation layer 180 and the second passivation layer 181 may include a general-purpose polymer such as polymethylmethacrylate (PMMA) or polystyrene (PS), a polymer derivative having a phenolic group, an acrylic polymer, an imide polymer, a polyimide, an acrylic polymer, an organic insulating material or an inorganic insulating material such as a siloxane-based polymer.

A pixel electrode 191 may be positioned on the second passivation layer 181. The pixel electrode 191 is electrically connected to the connection electrode 175 of the second data conductive layer through the contact hole 185 in the second passivation layer 181, and through this, the pixel electrode 191 is connected to the second electrode 133a of the first transistor DQ.

A pixel insulating layer 350 may be positioned on the pixel electrode 191. The pixel insulating layer 350 may also referred to as a wall and may have an opening 355 positioned over the pixel electrode 191. The pixel insulating layer 350 may include an organic insulating material such as polyimide, polyamide, acrylic resin, benzocyclobutene, or phenol resin. The pixel insulating layer 350 may include one or more separators 357.

FIG. 3 illustrates an example in which the separator 357 is formed on the top surface of the pixel insulating layer 350 and has a concave hole shape extending in the third direction DR3. A depth of the separator 357 in the third direction DR3 may be smaller than a thickness of the pixel insulating layer 350 in the third direction DR3. That is, the pixel insulating layer 350 may remain without being completely removed where the separator 357 is formed. As shown in FIG. 2, each separator 357 may have a shape extending along the periphery of each pixel electrode 191 in a plan view.

At least one light emitting auxiliary layer 371 and a light emitting layer 372 may be positioned on the pixel insulating layer 350 and the pixel electrode 191. The light emitting auxiliary layer 371 may include at least one of a hole injection layer, a hole transport layer, an electron injection layer, and an electron transport layer.

The light emitting layer 372 may include a light emitting material that emits light of a color represented by each pixel PX. Most of the light emitting layer 372 may be positioned within the opening 355 in the pixel insulating layer 350. In the opening 355, a portion of the light emitting auxiliary layer 371 may be positioned between the light emitting layer 372 and the pixel electrode 191, and a portion of the light emitting auxiliary layer 371 may be positioned on the light emitting layer 372.

In FIG. 3, only the light emitting auxiliary layer 371 positioned between the pixel electrode 191 and the light emitting layer 372 is shown, but at least one light emitting auxiliary layer may also be positioned on the pixel electrode 191. For example, when the pixel electrode 191 functions as an anode electrode, the light emitting auxiliary layer 371 positioned between the pixel electrode 191 and the light emitting layer 372 may include at least one of a hole injection layer and a hole transport layer, and a further light emitting auxiliary layer positioned on the light emitting layer 372 may include at least one of an electron injection layer and an electron transport layer.

The light emitting auxiliary layer 371 may also include a portion positioned on the pixel insulating layer 350. The light emitting auxiliary layer 371 may be cut off by the separator 357 positioned around the pixel electrode 191. Accordingly, the light emitting auxiliary layer 371 is not continuous between adjacent pixels and can be broken and separated by the separator 357 to prevent display defects due to lateral leakage between pixels PX. The light emitting auxiliary layer 371 may have a side end surface 375 overlapping the separator 357 or positioned around the separator 357. The side end surface 375 of the light emitting auxiliary layer 371 may or may not be aligned with the edge of the separator 357.

A common electrode 270 may be positioned on the light emitting auxiliary layer 371 and the light emitting layer 372. The common electrode 270 may function as a cathode electrode of a light emitting device. That is, the pixel electrode 191, the light emitting layer 372, and the common electrode 270 together may constitute a light emitting diode ED. The light emitting diode ED may include a light emitting auxiliary layer 371.

The common electrode 270 may be formed over a plurality of pixels and therefore may also include a portion positioned on the pixel insulating layer 350. Portions of the common electrode 270 may be cut off or separated by the separator 357 positioned around the pixel electrode 191. Accordingly, the common electrode 270 between adjacent pixels may include a discontinuous, disconnected portion. As shown in FIG. 2, the separators 357 located around each pixel electrode 191 are spaced apart from each other, so through the spaced areas 357s as shown in FIG. 2, the common electrodes 270 of neighboring pixels PX are electrically connected to each other, and the common voltage delivered by the common electrode 270 can be delivered to the entire display area DA. The common electrode 270 may have a side end face 275 overlapping the separator 357 or positioned around the separator 357. The side end face 275 of the common electrode 270 may or may not be aligned with the edge of the separator 357.

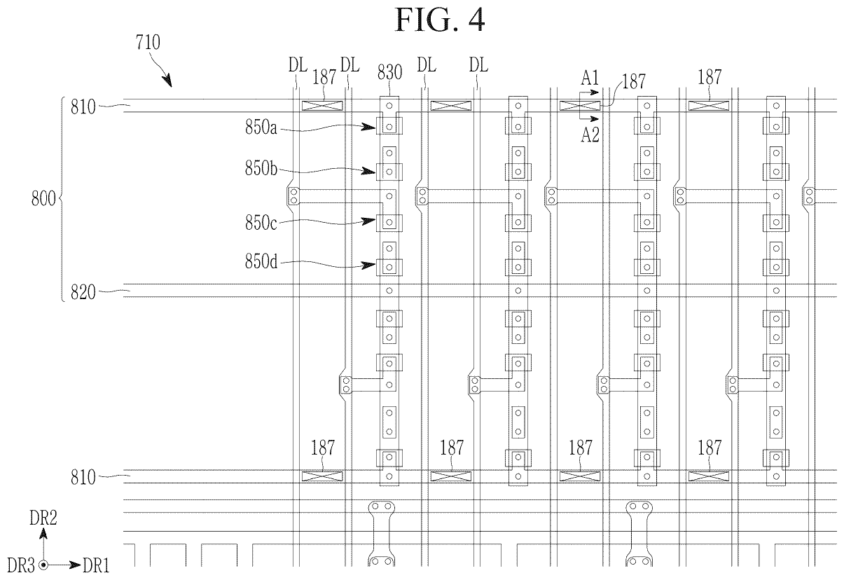

FIG. 4 is a top plan view of an electrostatic element unit in a peripheral area of a display device according to an embodiment.

Referring to FIG. 4, the electrostatic element unit 710 according to one embodiment may include a voltage line 800, a data line DL, and a plurality of static elements 850a, 850b, 850c, and 850d electrically connected to the voltage line 800 and the data line DL.

The voltage line 800 may include a low-voltage line 810 that transmits a low voltage and a high-voltage line 820 that transmits a higher voltage than the low-voltage line 810. In the electrostatic element unit 710, the low-voltage line 810 and the high-voltage line 820 may extend in a direction crossing the data lines DL.

The electrostatic elements 850a, 850b, 850c, and 850d may include various elements capable of discharging static electricity. For example, the electrostatic element may include an electrostatic diode or an electrostatic transistor. FIG. 4 shows an example in which the electrostatic element includes a plurality of electrostatic diodes. The plurality of electrostatic diodes may be connected in series and may include an electrostatic semiconductor layer 830 that may extend parallel to the data line DL.

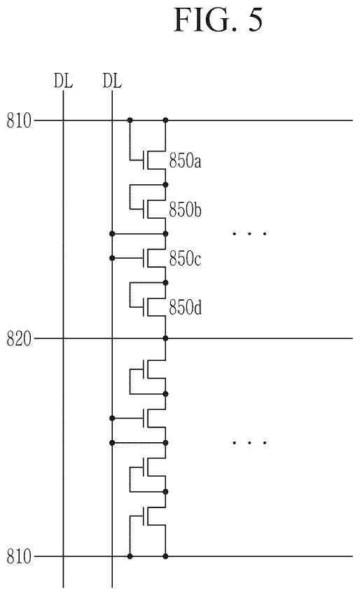

FIG. 5 is a circuit diagram of an electrostatic element unit in a peripheral area of a display device according to an embodiment. Referring to FIG. 5, each data line DL may be electrically connected to the low-voltage line 810 through two or more electrostatic elements 850a and 850b connected in series, and two or more electrostatic elements 850c and 850d may be electrically connected the data line DL to the high-voltage line 820.

Referring to FIG. 4, a plurality of contact holes 187 may be located at positions overlapping the low-voltage line 810 located in the electrostatic element unit 710. In the plan view shown in FIG. 4, a plurality of contact holes 187 may be arranged along each low-voltage line 810, and the spacing between and arrangement density of the plurality of contact holes 187 may be variously adjusted. For example, multiple contact holes 187 may be at locations where the data lines DL cross a low-voltage line 810. As shown in FIG. 4, one contact hole 187 may be provided for every two data lines DL. Alternatively, one contact hole 187 may also be provided for every three or more data lines DL. A contact hole 187 may be located between neighboring data lines DL in the electrostatic element unit 710, and the contact hole may not overlap with the planar line DL and also may not overlap with the static semiconductor layer 830. In the case where multiple low-voltage lines 810 are located in the electrostatic element unit 710, multiple contact holes 187 may overlap each low-voltage line 810 and may also overlap only some of the low-voltage lines 810.

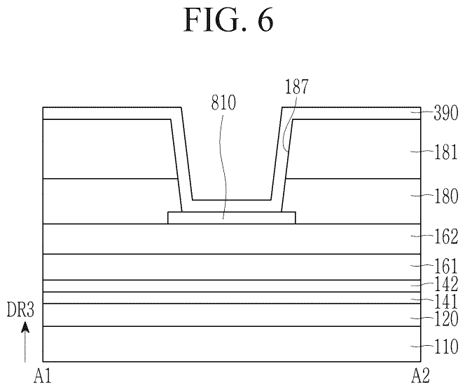

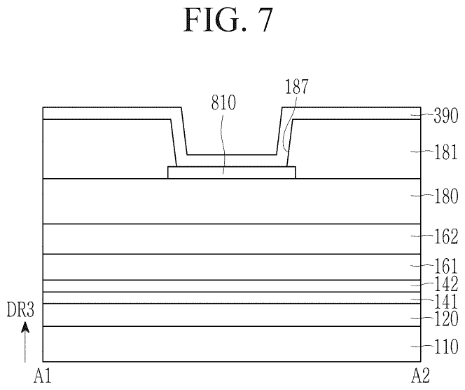

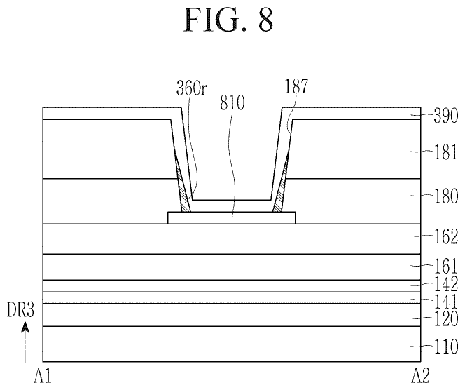

FIGS. 6, 7, and 8 are cross-sectional views taken along line A1-A2 in various embodiments of the display device shown in FIG. 4.

Referring to FIGS. 4 and 6, the low-voltage line 810 on the substrate 110 may be positioned in or formed from the first data conductive layer positioned on the second interlayer insulating layer 162. The contact hole 187 may be formed in the first passivation layer 180 and the second passivation layer 181 positioned on the low-voltage line 810. An encapsulation layer 390 may be positioned on the second passivation layer 181 and the exposed low-voltage line 810. The encapsulation layer 390 may include a plurality of insulating layers, and in particular, may include an inorganic insulating layer and an organic insulating layer that are alternately stacked. The encapsulation layer 390 may contact side surfaces of the first passivation layer 180 and the second passivation layer 181 defining the contact hole 187 and an upper side of the low-voltage line 810.

Referring to FIGS. 4 and 7, the low-voltage line 810 on the substrate 110 may be positioned in or formed from the second data conductive layer positioned on the first passivation layer 180. The contact hole 187 may be formed in the second passivation layer 181 positioned on the low-voltage line 810. The encapsulation layer 390 may be positioned on the second passivation layer 181 and the exposed low-voltage line 810. The encapsulation layer 390 may include a plurality of insulating layers, and in particular, may include an inorganic insulating layer and an organic insulating layer that are alternately stacked. The encapsulation layer 390 may contact the side surface of the second passivation layer 181 defining the contact hole 187 and the top surface of the low-voltage line 810.

Referring to FIGS. 4 and 8, the structure around the contact hole 187 according to the embodiment of FIG. 8 is mostly identical to the structure depicted in FIG. 6, but residue 360r can be located in some areas within the contact hole 187 as shown in FIG. 8. The residue 360r may include a material different from that of the first passivation layer 180 and the second passivation layer 181. The residue 360r may include, for example, a metal oxide such as IGZO. FIG. 8 illustrates an example where the low voltage line 810 is located in the first data conductive layer, but embodiments are not limited to this, and the low voltage line 810 may alternatively be located in the second data conductive layer, where the residue 360r may exist in some areas inside the contact hole 187 through the passivation layer 181.

In the case where a contact hole 187 is located on the low-voltage line 810 in the electrostatic element unit 710, the contact hole may not be located on the high-voltage line 820 in the electrostatic element unit 710 so that the high voltage line 820 may be completely covered by the second passivation layer 181.

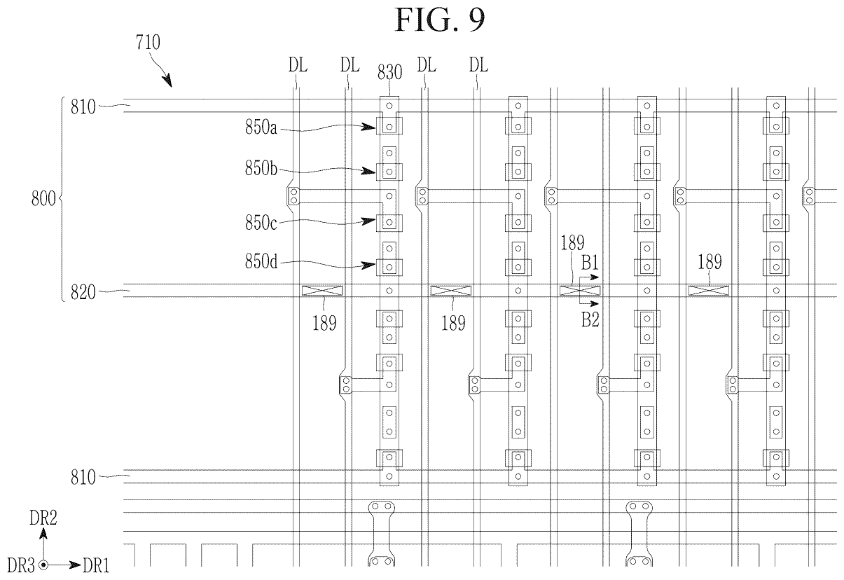

FIG. 9 shows a layout of an electrostatic element unit in a peripheral area of a display device according to an embodiment.

Referring to FIG. 9, a plurality of contact holes 189 may be located in the electrostatic element unit 710 at positions overlapping the high-voltage line 820. In the plan view shown in FIG. 9, a plurality of contact holes 189 may be arranged along each high-voltage line 820. The spacing between and arrangement density of the contact holes 189 may be variously adjusted. For example, multiple contact holes 189 can be arranged periodically at locations corresponding to where data lines DL cross the high-voltage line 820, and as shown in FIG. 9, one contact hole 189 may be provided for every two data lines DL. Alternatively, only one contact hole 189 may be provided for every three or more data lines DL. Each contact hole 189 can be located between neighboring data lines DL in the electrostatic element unit 710, and the contact holes 189 may not overlap with the data lines DL and also may not overlap with the semiconductor layer 830. In the case where multiple high-voltage lines 820 are located in the electrostatic element unit 710, multiple contact holes 189 can overlap each high-voltage line 820, and they can also overlap multiple contact holes 187 only on some of the high-voltage lines 820.

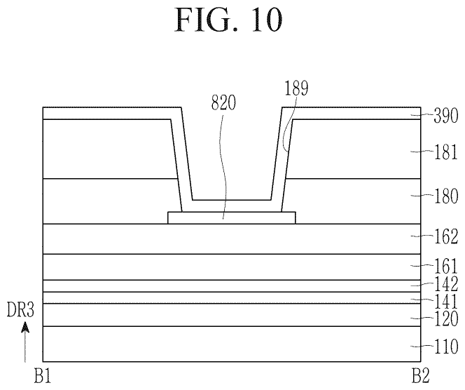

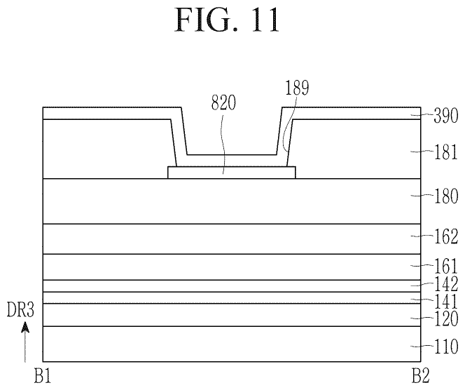

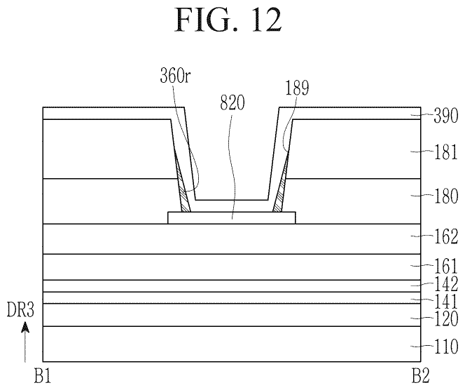

FIGS. 10, 11, and 12 are cross-sectional views taken along line B1-B2 in various embodiments of the display device shown in FIG. 9.

Referring to FIGS. 9 and 10, the high-voltage line 820 may be positioned on the substrate 110 in the first data conductive layer on the second interlayer insulating layer 162. The contact hole 189 may be formed in the first passivation layer 180 and the second passivation layer 181 on the high-voltage line 820. The encapsulation layer 390 may be on the second passivation layer 181 and extend into the contact hole 189 and onto the exposed portion of the high-voltage line 820. The encapsulation layer 390 may include a plurality of insulating layers, and in particular, may include an inorganic insulating layer and an organic insulating layer that are alternately stacked. The encapsulation layer 390 may contact side surfaces of the first passivation layer 180 and the second passivation layer 181 defining the contact hole 189 and may contact the upper side of the high-voltage line 820.

Referring to FIGS. 9 and 11, the high-voltage line 820 is positioned on the substrate 110 and may be a region of the second data conductive layer positioned on the first passivation layer 180. The contact hole 189 may be formed in the second passivation layer 181 positioned on the high-voltage line 820. The encapsulation layer 390 may be positioned on the second passivation layer 181 and may extend into the contact hole 189 and onto the exposed high-voltage line 820. The encapsulation layer 390 may include a plurality of insulating layers, and in particular, may include an inorganic insulating layer and an organic insulating layer that are alternately stacked. The encapsulation layer 390 may contact the side surface of the second passivation layer 181 defining the contact hole 189 and the top surface of the high-voltage line 820.

Referring to FIGS. 9 and 12, the structure around the contact hole 189 according to an embodiment shown in FIG. 12 may be substantially the same as the structure shown in FIG. 10, but the residue 360r containing a material different from that of the second passivation layer 181 may be located on the first passivation layer 180 or the second passivation layer 181. The residue 360r may include, for example, a metal oxide such as IGZO. FIG. 12 illustrates an example where a high-voltage line 820 is located in the first data conductive layer on the second interlayer insulating layer 162, but embodiments are not limited to this. For example, the high-voltage line 820 may be located in the second data conductive layer on the first passivation layer 180, the residues 360r may exist in some areas inside the contact hole 180.

In the case where a contact hole 189 is located on the high-voltage line 820 in the electrostatic element unit 710, the contact hole may not be located on the low-voltage line 810 located in the electrostatic element unit 710, and the low-voltage line 810 may be completely covered by the second passivation layer 181.

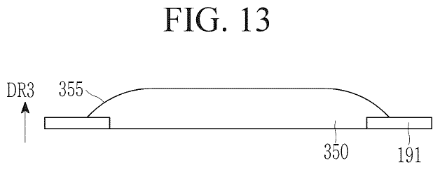

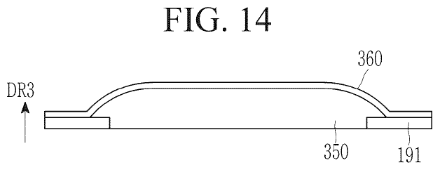

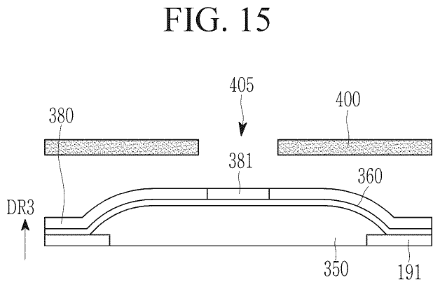

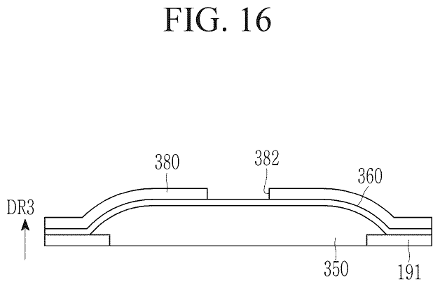

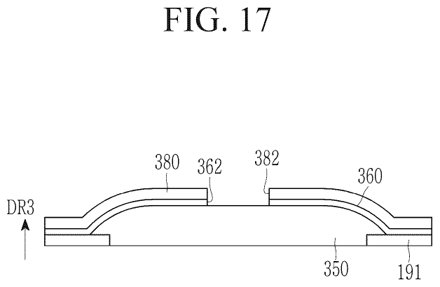

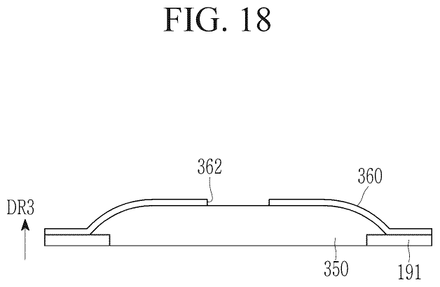

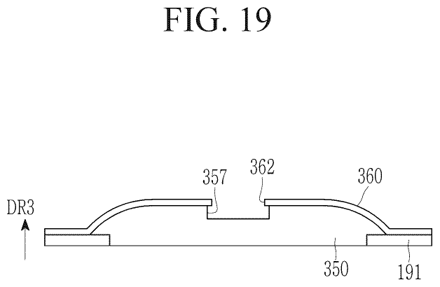

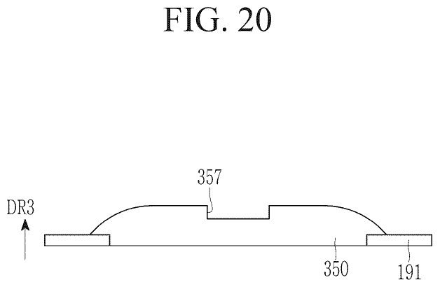

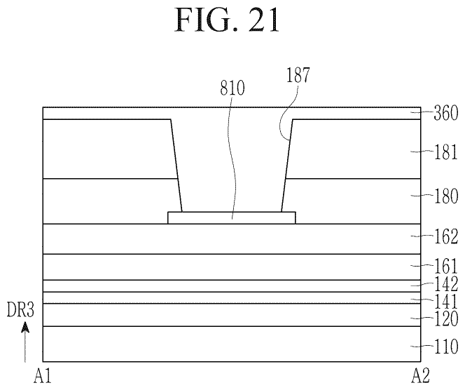

A manufacturing method of a display device according to an embodiment will be described with reference to FIGS. 13 to 24 together with the previously described drawings. FIG. 13, FIG. 14, FIG. 15, FIG. 16, FIG. 17, FIG. 18, FIG. 19, and FIG. 20 are cross-sectional views of structures in an area of a separator that may be formed during fabrication of a display device using a method of manufacturing according to an embodiment, and FIGS. 21 22, 23, and 24 are cross-sectional views in an area of a contact hole in an electrostatic element unit of a display device produced in a manufacturing method of a display device according to an embodiment.

Referring to FIG. 13 together with FIG. 3 described above, a manufacturing method of a display device according to an embodiment may sequentially stack the first insulating layer 120 to the second passivation layer 181 on the substrate 110 as shown in FIG. 3, and after necessary patterning, a plurality of pixel electrodes 191 are formed on the second passivation layer 181. Subsequently, the pixel insulating layer 350 is stacked on the plurality of pixel electrodes 191 and patterned to form openings 355 positioned on the pixel electrodes 191 as shown in FIG. 13.

Referring to FIGS. 3 and 14, a mask layer 360 is stacked on the entire surface of the substrate 110. The mask layer 360 on the pixel insulating layer 350 includes a portion positioned in the display area DA and a portion positioned in the peripheral area PA including the electrostatic element unit 710 and may be connected as a whole as one layer. The mask layer 360 may include a material different from the material of the pixel insulating layer 350 and may include a material having an etch rate different from that of the pixel insulating layer 350. For example, the mask layer 360 may include a metal oxide such as IGZO. The mask layer 360 may contact top surfaces of the pixel electrodes 191 and the pixel insulating layer 350.

Referring to FIG. 15, a photoresist 380 is deposited on the mask layer 360 and a photomask 400 is placed thereon. Light such as ultraviolet (UV) light is radiated through an opening 405 of the photomask 400. The photoresist 380 may have a positive photosensitivity such that a portion 381 irradiated with light is removed, but embodiments are not limited thereto. The opening 405 of the photomask 400 or the portion 381 of the photoresist 380 may be positioned between pixel electrodes 191 adjacent to each other on a plane and may not overlap the pixel electrodes 191.

Referring to FIG. 16, the portion 381 of the photoresist 380 exposed to light is removed to form an opening 382 in the photoresist 380, and a portion of the corresponding mask layer 360 is exposed.

Referring to FIG. 17, an opening 362 in the mask layer 360 is formed by etching and removing (patterning) the mask layer 360 exposed through the opening 382 of the photoresist 380. Etching of the mask layer 360 may use wet etching. The opening 362 may be between adjacent pixel electrodes 191.

Referring to FIGS. 17 and 18, the photoresist 380 may be removed by a strip process or the like.

Referring to FIG. 19, a portion of the upper surface of the pixel insulating layer 350 corresponding to the opening 362 is removed by a method such as ashing using the mask layer 360 having the opening 362 as a mask on the pixel insulating layer 340. This removal process applied to the pixel insulating layer 350 forms a separator 357 having a concave hole shape on the upper surface of the pixel insulating layer 350. The separator 357 may have a greater width than the opening 362 of the mask layer 360.

Referring to FIGS. 19 and 20, the mask layer 360 is removed from the entire surface of the substrate 110. In this case, wet etching may be used.

Referring to FIG. 3, after removing the mask layer 360, an auxiliary emission layer 371 may be stacked on the pixel electrode 191 and the pixel insulating layer 350. At this time, regions of the light emitting auxiliary layer 371 may be separated from each other or cut off due to a step by the separator 357. Later, even in the step of forming the common electrode 270 on the light emitting auxiliary layer 371, the separator 357 may cause a cut off in the common electrode 270.

Referring to FIG. 21, in the process according to the manufacturing method of the display device described above, the first insulating layer 120 to the second passivation layer 181 are sequentially stacked on the substrate 110, and then patterning of the second passivation layer 181 and the first passivation layer 180 may form the contact hole 187 on the low-voltage line 810 in the electrostatic element unit 710. Afterwards, during the process described with reference to FIG. 14, when the mask layer 360 is laminated, the mask layer 360 can be electrically connected by contacting the low-voltage line 810 through the contact hole 187 through the first and second passivation layers 180 and 181 in the electrostatic element unit 710. The mask layer 360 connected to the low-voltage line 810 may be removed as the mask layer 360 is removed in the process of FIG. 20 described above. Accordingly, as described in FIG. 6, the mask layer 360 connected to the low-voltage line 810 can be completely removed, or as shown in FIG. 8, the residue 360r of the mask layer 360 can remain inside the contact hole 187.

Referring to FIG. 22, in the process according to the manufacturing method of the display device described above, the first insulating layer 120 to the second passivation layer 181 are sequentially stacked on the substrate 110, and then the second passivation layer 181 is formed. Patterning may form contact hole 187 on the low-voltage line 810 positioned in the electrostatic element unit 710. Afterwards, in the process described in FIG. 14 explained earlier, when the mask layer 360 is laminated, the mask layer 360 can be electrically connected by contacting the low-voltage line 810 through the contact hole 187 in the electrostatic element unit 710. The mask layer 360 connected to the low-voltage line 810 may be removed as the mask layer 360 is removed in the process of FIG. 20 described above. Accordingly, the mask layer 360 connected to the low-voltage line 810 may be completely removed from the contact hole 187 as shown in FIG. 7 described above or residue 360r of the mask layer 360 may remain inside the contact hole 187.

Referring to FIG. 23, in the process according to the manufacturing method of the display device described above, the first insulating layer 120 to the second passivation layer 181 are sequentially stacked on the substrate 110, and then the contact hole 189 in the first and second passivation layers 180 and 181 may be formed on the high-voltage line 820 positioned in the electrostatic element unit 710 by patterning the first and second passivation layers 180 and 181. Then, when the mask layer 360 is stacked in the process shown in FIG. 14 described above, the mask layer 360 electrically contacts the high-voltage line 820 through the contact hole 189 in the electrostatic element unit 710. The mask layer 360 connected to the high-voltage line 820 may be removed as the mask layer 360 is removed in the process of FIG. 20 described above. Accordingly, as described above and shown in FIG. 10, the mask layer 360 connected to the high-voltage line 820 can be completely removed as shown in FIG. 10, or the residue 360r of the mask layer 360 can remain inside the contact hole 189 as shown in FIG. 12.

Referring to FIG. 24, in the process according to the manufacturing method of the display device described above, after sequentially stacking the first insulating layer 120 to the second passivation layer 181 on the substrate 110, and patterning may form a contact hole 189 in the second passivation layer 181 on the high-voltage line 820 positioned in the electrostatic element unit 710. Afterwards, in the process described in FIG. 14, when the mask layer 360 is laminated, the mask layer 360 can be electrically connected by contacting the high-voltage line 820 through the contact hole 189 in the electrostatic element unit 710. The mask layer 360 connected to the high-voltage line 820 may be removed as the mask layer 360 is removed in the process of FIG. 20 described above. Accordingly, the mask layer 360 connected to the high-voltage line 820 may be completely removed as shown in FIG. 11 described above, or the residue 360r of the mask layer 360 may remain inside the contact hole 189.

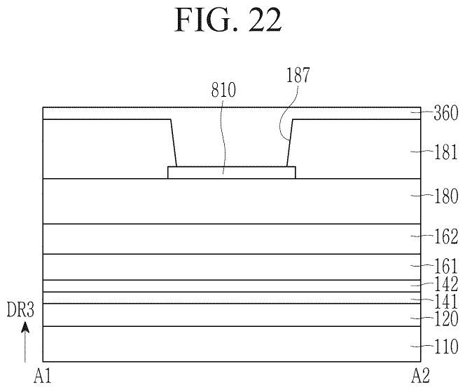

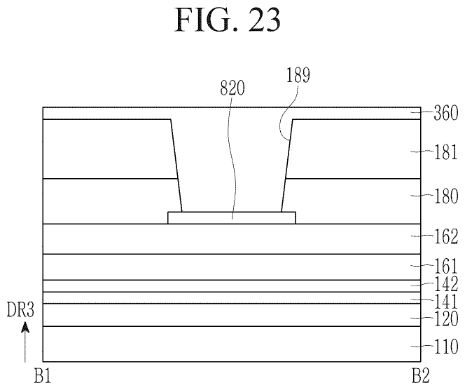

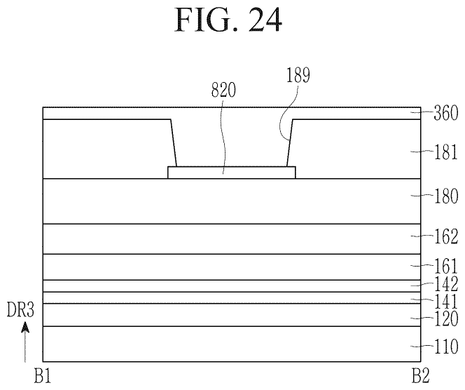

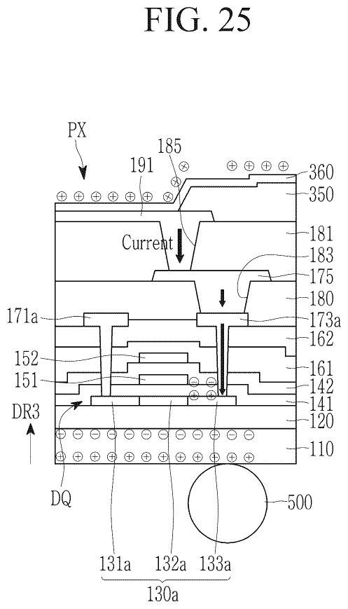

In FIG. 13 to FIG. 24, in the process of forming the separator 357 on the upper surface of the pixel insulating layer 350, the mask layer 360 is also in the peripheral area PA or the low-voltage line 810. Since the mask layer 360 is electrically connected to the low-voltage line 810 or the high-voltage line 820, static charge generated during the process may flow from the mask layer 360 to the low-voltage line 810 or the high-voltage line 820 and escape. Therefore, the mask layer 360 can prevent the characteristics of the first transistor DQ (as shown in FIGS. 3 and 14) from changing by coming into contact with the pixel electrode 191 and transmitting static electricity through the pixel electrode 191 to the first transistor DQ. These effects are described below in comparison with the comparative examples shown in FIGS. 25 to 27.

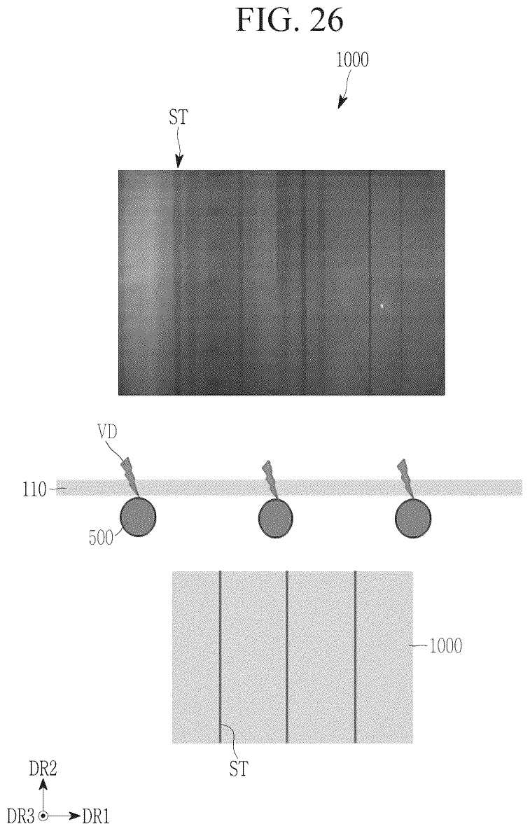

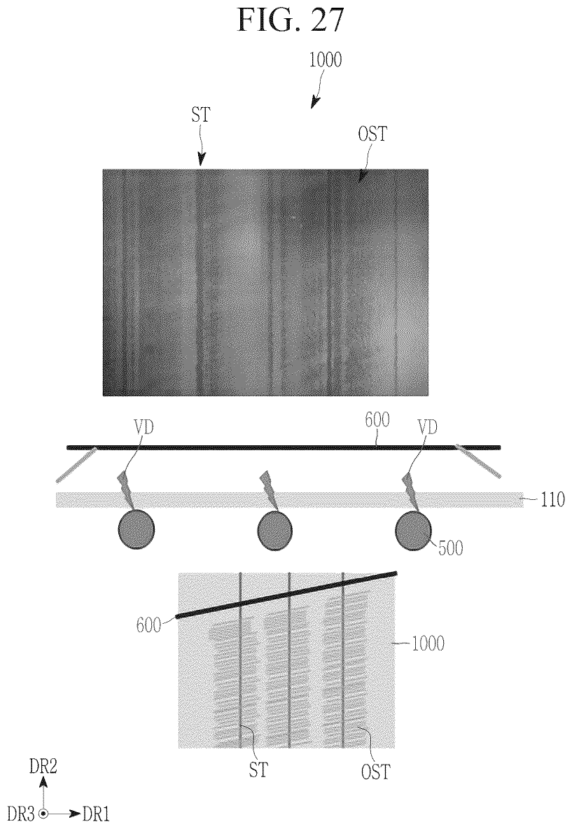

FIG. 25 is a cross-sectional view of a display device in a manufacturing process according to a comparative example, and FIGS. 26 and 27 are drawings showing a stain displayed in an image of a display device in a manufacturing process according to each comparative example.

Referring to FIG. 25, in various stages of the process described in FIGS. 13 to 20, for example, pre-cleaning before exposure after the deposition of the mask layer 360, the stripping process for the removal of photoresist, the removal of the mask layer 360, etc., a roller 500 for equipment transportation may cause electrostatic discharge due to the static electricity generated by contact with the substrate 110, and the part of the substrate 110 adjacent to the roller 500 can be electrified. Charges charged on the substrate 110 may be transferred to the dielectrics of the layers stacked thereon, so that the upper mask layer 360 may also be charged, and the charge of the mask layer 360 may be transferred through the pixel electrode 191, the connection electrode 175, and the connection electrode 173a to the first transistor DQ. Accordingly, due to a change in the characteristics of the first transistor DQ, a stain may appear on an image displayed by the display device.

FIG. 26 shows the substrate 110 being transferred or moved on rollers 500 during manufacturing of the display device 1000. Referring to FIG. 26, for each roller 500, a discharge or additional charge compared to the surroundings may be generated at a position corresponding to the roller 500, causing the substrate 110 to be charged by friction with the roller 500 positioned under the substrate 110 of the display device 1000. Accumulation of charge can generate a potential difference VD. Then, the characteristics of the transistor (for example, the first transistor DQ) of the pixel at the position corresponding to the roller 500 may change compared to the surroundings, and as shown in FIG. 26, a stain ST may occur on the image displayed by the display device 1000.

Referring to FIGS. 26 and 27 together, in the manufacturing process of the display device 1000, when an air knife 600 is used to remove solution after cleaning or wet etching, the air pressure from the air knife 600 can cause a slight vibration of the substrate 110 in a diagonal direction as shown in FIG. 27. This can cause a change in the characteristics of the corresponding pixel's transistor, which can also result in the appearance of diagonal stains OST on the image of the display device 1000.

However, according to the present embodiment, during the manufacturing process of the display device, the mask layer 360, which affects characteristics by flowing a current due to charging the transistor (e.g., the first transistor DQ) of the pixel, is formed in the peripheral area PA and is electrically connected to the low-voltage line 810 or the high-voltage line 820. Accordingly, static charge generated during the process can flow from the mask layer 360 to the low-voltage line 810 or the high-voltage line 820 and escape. Therefore, the mask layer 360 may contact the pixel electrode 191 to prevent electrostatic charge from being transferred to the first transistor DQ through the pixel electrode 191 and changing the characteristics of the first transistor DQ. Accordingly, it is possible to prevent occurrence of display defects such as spot (ST) or oblique line spot OST as shown in FIGS. 26 and 27.

Although some specific embodiments have been described in detail above, the scope of the present disclosure is not limited thereto, and various modifications and improvements made by those skilled in the art using the basic concepts of the present disclosure are also included in the scope defined in the following claims.

### DESCRIPTION OF SYMBOLS

110: substrate
120: insulating layer
121: lower layer
130a, 130b, 830: semiconductor layer
141, 142, 143: gate insulating layer
151, 153: gate electrode
152: storage electrode
161, 162: interlayer insulating layer
171a, 171b, 173a, 173b, 175: connection electrode
180, 181: passivation layer
183, 185, 187, 189: contact hole
191, 191a, 191b, 191c: pixel electrode
270: common electrode
350: pixel insulating layer
355, 362, 382, 405: opening
357: separator
360: mask layer
371: light emitting auxiliary layer
372: light emitting layer
380: photoresist
390: encapsulation layer
400: photomask
500: roller
600: air knife
700: scan driver
710: electrostatic element unit
720: pad unit
800, 810, 820: voltage line
850a, 850b, 850c, 850d: electrostatic element
1000: display device

What is claimed is:

1. A display device, comprising:
a display area including a plurality of pixels and a separator extending along a periphery of the pixels; and
a peripheral area located around the display area and including a scan driver and an electrostatic element unit,
wherein each of the pixels includes a pixel electrode, a portion of a light emitting auxiliary layer positioned on the pixel electrode, and a portion of a common electrode positioned on the light emitting auxiliary layer,
between adjacent pixels, the separator disconnects the portions of the light emitting auxiliary layer,
the electrostatic element unit includes a first voltage line electrically connected to the scan driver and a plurality of electrostatic elements electrically connected to the first voltage line,
a plurality of contact holes overlapping the first voltage line located in the electrostatic element unit, and
an insulating layer is located in the contact holes.

2. The display device of claim 1, further comprising:
a protective layer positioned on the first voltage line and having the contact hole formed therein, and
the insulating layer is in contact with a side surface of the passivation layer defining the contact hole and an upper surface of the first voltage line.

3. The display device of claim 2, wherein:
the insulating layer includes a portion positioned on an upper surface of the passivation layer.

4. The display device of claim 2, further comprising:
a pixel insulating layer positioned on the passivation layer and the pixel electrodes, and
the separator is formed in a concave shape on the upper surface of the pixel insulating layer.

5. The display device of claim 4, further comprising
a substrate, wherein
each of the pixels further comprises a transistor positioned between the substrate and the passivation layer, the transistor being electrically connected to the pixel electrode.

6. The display device of claim 5, further comprising:
a plurality of data lines connected to the electrostatic element unit, wherein
the data lines cross the first voltage line, and
the contact holes are located between adjacent data lines among the plurality of data lines.

7. The display device of claim 6, wherein:
the electrostatic element unit further includes an electrostatic semiconductor layer forming the plurality of electrostatic elements, and
the contact holes do not overlap with the electrostatic semiconductor layer on a plane.

8. The display device of claim 2, further comprising:
residue including a metal oxide in a partial region within the contact hole.

9. The display device of claim 1, further comprising:
a light emitting layer positioned between the pixel electrode and the common electrode or between the light emitting auxiliary layer and the pixel electrode.

10. A display device, comprising:
a substrate including a display area and a peripheral area positioned outside the display area;
a transistor located on the display area;
an electrostatic element positioned on the peripheral area and a first voltage line, and a second voltage line electrically connected to the electrostatic element;
a passivation layer positioned on the transistor, the first voltage line, and the second voltage line;
a plurality of pixel electrodes positioned on the passivation layer and positioned in the display area;
a pixel insulating layer positioned on the passivation layer and the pixel electrode, and
a light emitting auxiliary layer and a light emitting layer positioned on the pixel electrode and the pixel insulating layer,
the pixel insulating layer is positioned between adjacent pixel electrodes among the plurality of pixel electrodes and includes a concave separator, and
the passivation layer has a contact hole positioned on the first voltage line in the peripheral area.

11. The display device of claim 10, wherein:
the passivation layer covers all of the second voltage line in the peripheral area.

12. The display device of claim 10, further comprising:
a plurality of data lines connected to the plurality of electrostatic elements, wherein
the data lines cross the first voltage line and the second voltage line, and
the contact holes are located between adjacent data lines among the plurality of data lines on a plane.

13. The display device of claim 12, wherein:
the electrostatic element unit further includes an electrostatic semiconductor layer forming the plurality of electrostatic elements, and
the contact holes do not overlap the electrostatic semiconductor layer on a plane.

14. The display device of claim 10, wherein:
the display device further comprises residue including a metal oxide in a partial region within the contact hole.

15. The display device of claim 10, further comprising:
an insulating layer including a portion positioned within the contact hole and contacting a side surface of the passivation layer defining the contact hole and an upper surface of the first voltage line.

16. The display device of claim 15, wherein:
the insulating layer includes a portion positioned on an upper surface of the passivation layer.

17. The display device of claim 10, wherein:
the separator disconnects portions of the light emitting auxiliary layer.

18. A method for manufacturing a display device, comprising:
forming a plurality of transistors positioned over a display area on a substrate;
forming a plurality of electrostatic elements and voltage lines located in a peripheral area located around the display area;
laminating a passivation layer on the voltage line;
forming a contact hole exposing the voltage line located in the peripheral area in the passivation layer;
forming a plurality of pixel electrodes in the display area;
forming a pixel insulating layer on the pixel electrode and patterning the pixel insulating layer to form a first opening positioned on the pixel electrode;
depositing a mask layer over the entire surface of the substrate, the mask layer being electrically connected to the voltage line through the contact hole;
patterning the mask layer to form a second opening positioned between adjacent pixel electrodes among the plurality of pixel electrodes;
forming a concave hole-shaped separator on the upper surface of the pixel insulating layer by removing a portion of the upper surface of the pixel insulating layer corresponding to the second opening using the second opening as a mask, and
removing the mask layer over the front surface of the substrate.

19. A method for manufacturing a display device of claim 18, wherein:
the mask layer includes a metal oxide.

20. A method for manufacturing a display device of claim 18, further comprising:
stacking a light emitting auxiliary layer on the pixel electrode and the pixel insulating layer,
forming a common electrode on the light emitting auxiliary layer, and
forming an insulating layer on the substrate, wherein
the light emitting auxiliary layer includes a portion cut off by the separator, and
the insulating layer includes a portion located in the contact hole.
